(19) United States
(12) Patent Application Publication
(10) Pub. No.: US 2025/0343105 A1
(43) Pub. Date: Nov. 6, 2025

(54) POWER CONVERSION DEVICE

(71) Applicant: DENSO CORPORATION, Kariya-city (JP)

(72) Inventors: Kazuya MOTOMURA, Kariya-city (JP); Yuta HASHIMOTO, Kariya-city (JP)

(73) Assignee: DENSO CORPORATION, Kariya-city (JP)

(21) Appl. No.: 19/265,570

(22) Filed: Jul. 10, 2025

Related U.S. Application Data
(63) Continuation of application No. PCT/JP2024/000932, filed on Jan. 16, 2024.

(30) Foreign Application Priority Data
Feb. 17, 2023 (JP) 2023-023516

(51) Int. Cl. H01L 23/42; H01L 23/473; H01L 23/49; H01L 25/065; H01L 25/16; H02M 7/00

(52) U.S. Cl. CPC H01L 23/42; H01L 23/473; H01L 23/49; H01L 25/0655; H01L 25/165; H02M 7/003

(57) ABSTRACT

A power conversion device includes a first cooler, a semiconductor module, and a second cooler. In Z direction, the first cooler, the semiconductor module, and the second cooler are stacked in this order. The external connection terminals of the semiconductor module include a main terminal electrically connected to a capacitor and a signal terminal which is a bent terminal. The signal terminal has a first extension portion extending on the same side as the main terminal, and a second extension portion bent relative to the first extension portion, extending in the Z direction, and facing the second cooler in Y direction. In the Y direction, a length of the second cooler is shorter than a length of the first cooler. In the Y direction, a distance between the second extension portion and the second cooler is shorter than a distance between the second extension portion and the first cooler.

### CROSS REFERENCE TO RELATED APPLICATIONS

The present application is a continuation application of International Patent Application No. PCT/JP2024/000932 filed on Jan. 16, 2024, which designated the U.S. and claims the benefit of priority from Japanese Patent Application No. 2023-023516 filed in Japan filed on Feb. 17, 2023, the entire disclosure of the above application is incorporated herein by reference.

### TECHNICAL FIELD

The present disclosure relates to a power conversion device.

### BACKGROUND

A power conversion device is known.

### SUMMARY

It is an object of the disclosure to provide a power control device with a reduced inductance.

The power conversion device disclosed herein includes a first cooler, a semiconductor module including a main body including a semiconductor element, and a plurality of external connection terminals electrically connected to the semiconductor element, and a second cooler stacked on the semiconductor module on an opposite side to the first cooler so as to face the rear surface.

A length of the second cooler is shorter than a length of the first cooler in one direction perpendicular to a stacking direction of the semiconductor module, the first cooler, and the second cooler.

A plurality of external connection terminals include main terminals having a portion extending in the one direction and electrically connected to a smoothing capacitor, and bent terminals having a first extension portion extending in the one direction on the same side of the semiconductor element as the main terminal, and a second extension portion bent with respect to the first extension portion, extending in the stacking direction, and facing the second cooler in the one direction.

In the one direction, a distance between the second extension portion and the second cooler is shorter than a distance between the second extension portion and the first cooler.

### BRIEF DESCRIPTION OF DRAWINGS

FIG. 1 is a diagram showing a circuit configuration and a drive system of a power conversion device according to a first embodiment;

FIG. 2 is a plan view illustrating the power conversion device;

FIG. 3 is a cross-sectional view taken along a line III-III of FIG. 2.

FIG. 4 is a diagram showing a positional relationship between a signal terminal, a first cooler, and a second cooler;

FIG. 5 is a cross-sectional view showing a modified example;

FIG. 6 is a cross-sectional view showing a modified example;

FIG. 7 is a diagram showing a positional relationship between a signal terminal, a first cooler, and a second cooler in the power conversion device according to a second embodiment;

FIG. 8 is a diagram showing a positional relationship between a signal terminal, a first cooler, and a second cooler in the power conversion device according to a third embodiment; and

FIG. 9 is a diagram showing a positional relationship between a signal terminal, a first cooler, and a second cooler in the power conversion device according to a fourth embodiment.

### DETAILED DESCRIPTION

A power conversion device is known. The disclosure of JP 2021-97101 A (corresponding to US-A1-2023/0023345) is incorporated herein by reference as explanation of the technical elements in this disclosure.

The power conversion device has a main body in which a power semiconductor device is resin-sealed, a first cooler provided on a collector side of the power semiconductor device, and a second cooler provided on an emitter side thereof. Of the plurality of external connection terminals electrically connected to the power semiconductor device, a positive pole side terminal and a negative pole side terminal, which are the main terminals electrically connected to a smoothing capacitor, extend in one direction and protrude from a common side of the sealing resin respectively. A part of the signal terminal also extends in one direction and protrudes from the common side together with the positive and negative terminals. The signal terminal bends outside the sealing resin and extend in a stacking direction, facing the second cooler in one direction.

It is difficult to shorten a distance between the power semiconductor device and the smoothing capacitor because of bent terminal such as signal terminal. In other words, it is difficult to reduce an inductance of a wiring connecting the power semiconductor device and the smoothing capacitor. From the viewpoint described above or from other unmentioned viewpoints, there is a demand for further improvement to the power control device.

It is an object of the disclosure to provide a power control device with a reduced inductance.

The power conversion device disclosed herein includes:
a first cooler,
a semiconductor module including a main body including a semiconductor element having a first main electrode formed on one surface facing the first cooler and a second main electrode and a pad for signal formed on a rear surface opposite to the one surface, and a plurality of external connection terminals electrically connected to the semiconductor element, the semiconductor module being stacked on the first cooler, and
a second cooler stacked on the semiconductor module on an opposite side to the first cooler so as to face the rear surface.

A length of the second cooler is shorter than a length of the first cooler in one direction perpendicular to a stacking direction of the semiconductor module, the first cooler, and the second cooler.

A plurality of external connection terminals include main terminals having a portion extending in the one direction and electrically connected to a smoothing capacitor, and bent terminals having a first extension portion extending in the one direction on the same side of the semiconductor element as the main terminal, and a second extension portion bent with respect to the first extension portion, extending in the stacking direction, and facing the second cooler in the one direction.

In one direction, a distance between the second extension portion and the second cooler is shorter than a distance between the second extension portion and the first cooler.

According to the disclosed power conversion device, the second cooler is made shorter than the first cooler in one direction, and the second extension portion of the bent terminal is brought closer to the second cooler. This allows the smoothing capacitor to be located close to the main body of the semiconductor module while avoiding interference with the bent terminal. Therefore, the inductance of the wiring connecting the semiconductor element and the smoothing capacitor can be reduced.

Hereinafter, a plurality of embodiments will be described with reference to the drawings. The same reference numerals are assigned to the corresponding elements in each embodiment, and thus, duplicate descriptions may be omitted. When only a part of the configuration is described in the respective embodiments, the configuration of the other embodiments described before may be applied to other parts of the configuration. Further, not only the combinations of the configurations explicitly shown in the description of the respective embodiments, but also the configurations of the plurality of embodiments can be partially combined even when they are not explicitly shown as long as there is no difficulty in the combination in particular.

The power conversion device according to the present embodiment is applicable to, e.g., a movable object with a rotary electric machine as a drive source. The movable object is, for example, an electrically driven vehicle such as an electric vehicle (BEV), a hybrid vehicle (HEV), or a plug-in hybrid vehicle (PHEV), an electric flying object, a ship, a construction machine, or an agricultural machine. The electric flying object may be, for example, a drone or an electric vertical takeoff and landing aircraft (eVTOL). Hereinafter, an example applied to a vehicle will be described.

### First Embodiment

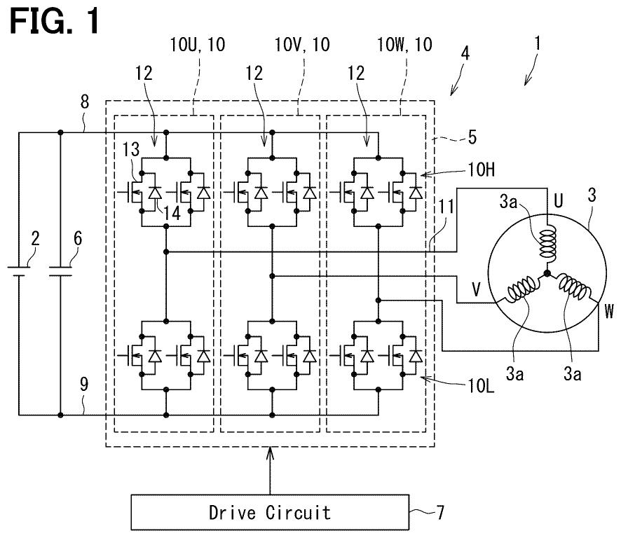

First, a schematic configuration of a vehicle drive system is described with reference to FIG. 1.

### Vehicle Drive System:

As shown in FIG. 1, the vehicle drive system 1 is provided with a direct current (DC) power supply 2, a motor generator 3, and a power conversion device 4.

The DC power supply 2 is a direct-current voltage source including a chargeable and dischargeable secondary battery. The secondary battery may be a lithium ion battery, a nickel-hydrogen battery, or an organic radical battery. The motor generator 3 is a three-phase AC type rotating electric machine. The motor generator 3 functions as a vehicle driving power source, i.e., an electric motor. The motor generator 3 functions as a generator during regeneration. The power conversion device 4 performs electric power conversion between the DC power supply 2 and the motor generator 3.

### Circuit Configuration of Power Conversion Device:

FIG. 1 shows a circuit configuration of the power conversion device 4. The power conversion device 4 includes at least a power conversion circuit. The power conversion device in the present embodiment is an inverter 5. The power conversion device 4 may be further equipped with a smoothing capacitor 6 and a drive circuit 7.

The smoothing capacitor 6 mainly smooths the DC voltage supplied from the DC power supply 2. The smoothing capacitor 6 is connected between a P-line 8 which is a power line on a high potential side and an N-line 9 which is a power line on a low potential side. The P-line 8 is connected to a positive electrode of the DC power supply 2, and the N-line 9 is connected to a negative electrode of the DC power supply 2. The positive electrode of the smoothing capacitor 6 is connected to the P line 8 between the DC power supply 2 and the inverter 5. The negative electrode of the smoothing capacitor 6 is connected to the N-line 9 at a position between the DC power supply 2 and the inverter 5. The smoothing capacitor 6 is connected in parallel with the DC power supply 2.

The inverter 5 corresponds to a DC-AC conversion circuit. The inverter 5 converts a DC voltage into a three-phase AC voltage, and outputs the AC voltage to the motor generator 3 according to switching control by a control circuit (not illustrated). Thereby, the motor generator 3 is driven to generate a predetermined torque. At the time of regenerative braking of the vehicle, the inverter 5 converts the three-phase AC voltage generated by the motor generator 3 by receiving the rotational force from the wheels into a DC voltage according to the switching control by the control circuit, and outputs the DC voltage to the P line 8. In this way, the inverter 5 performs bidirectional power conversion between the DC power supply 2 and the motor generator 3.

The inverter 5 includes upper and lower arm circuits 10 for three phases. The upper and lower arm circuits 10 may be referred to as legs. Each of the upper and lower arm circuits 10 has an upper arm 10H and a lower arm 10L. The upper arm 10H and the lower arm 10L are connected in series between the P-line 8 and the N-line 9 with the upper arm 10H is connected to the P-line 8.

A connection point between the upper arm 10H and the lower arm 10L, i.e., a midpoint of the upper and lower arm circuits 10, is connected to a winding 3a of the corresponding phase in the motor generator 3 via an output line 11. Of the upper and lower arm circuits 10, the U-phase upper and lower arm circuit 10U is connected to the U-phase winding 3a via the output line 11. The V-phase upper and lower arm circuit 10V is connected to the V-phase winding 3a via the output line 11. The W-phase upper and lower arm circuit 10W is connected to the W-phase winding 3a via the output line 11.

The upper and lower arm circuits 10 (10U, 10V, 10W) have the series circuit 12. The upper and lower arm circuits 10 may have one or more series circuits 12. In the case of a plurality of series circuits 12, the series circuits 12 are connected in parallel to each other to form the upper and lower arm circuit 10 for one phase. In the present embodiment, each of the upper and lower arm circuits 10 has one series circuit 12. The series circuit 12 is configured by connecting a switching element on the upper arm 10H side and a switching element on the lower arm 10L side in series between the P line 8 and the N line 9.

The number of switching elements on the high side and the number of switching elements on the low side constituting the series circuit 12 are not particularly limited. The number thereof may be one or more. The series circuit 12 of the present embodiment has two switching elements on the high side and two switching elements on the low side. Two switching elements on the high side are connected in parallel, and two switching elements on the low side are connected in parallel to form one series circuit 12. That is, each of the six arms 10H, 10L of the upper and lower arm circuits 10 for three phases is composed of two switching elements connected in parallel to each other.

In the present embodiment, an n-channel MOSFET 13 is used as each switching element. MOSFET is an abbreviation for Metal Oxide Semiconductor Field Effect Transistor. Two MOSFETs 13 on the high side connected in parallel are turned on and off at the same timing by a common gate drive signal (drive voltage). Two MOSFETs 13 on the low side connected in parallel are turned on and off at the same timing by a common gate drive signal (drive voltage).

A freewheeling diode 14 (hereinafter, referred to as FWD 14) is connected in anti-parallel to each of the MOSFETs 13. In the case of the MOSFET 13, the FWD 14 may be a parasitic diode (body diode) or an external diode. In the upper arm 10H, the drain of the MOSFET 13 is connected to the P line 8. In the lower arm 10L, the source of the MOSFET 13 is connected to the N line 9. The drain of the MOSFET 13 in the upper arm 10H and the drain of the MOSFET 13 in the lower arm 10L are connected to each other. The anode of the FWD 14 is connected to the source of the corresponding MOSFET 13, and the cathode is connected to the drain.

The switching element is not limited to the MOSFET 13. For example, an IGBT may be used. The IGBT is an abbreviation of an insulated gate bipolar transistor. In the case of the IGBT, the FWD 14 is also connected in inverse parallel.

The drive circuit 7 drives switching elements that constitute the power conversion circuit such as the inverter 5. The drive circuit 7 supplies a drive voltage to the gate of the MOSFET 13 of the corresponding arm based on the drive command of the control circuit. The drive circuit drives the corresponding MOSFET 13 by applying a drive voltage to turn on and off the drive of the corresponding MOSFET 13. The drive circuit may also be referred to as a driver.

The power control device 4 may include a control circuit for the switching element. The control circuit generates a drive command for operating the MOSFET 13 and outputs the drive command to the drive circuit 7. The control circuit generates a drive command based on a torque request input from a host ECU (not illustrated) and signals detected by various sensors. ECU is an abbreviation of Electronic Control Unit. The control circuit may be provided within the host ECU.

Various sensors include, for example, a current sensor, a rotation angle sensor, and a voltage sensor. The power control device 4 may include at least one sensor. The current sensor detects a phase current flowing through the winding 3a of each phase. The rotation angle sensor detects a rotation angle of a rotor of the motor generator 3. The voltage sensor detects the voltage across the smoothing capacitor 6. The control circuit includes, for example, a processor and a memory. The control circuit outputs, e.g., a PWM signal as the drive command. PWM is an abbreviation for Pulse Width Modulation.

The power conversion device 4 may further include a converter as the power conversion circuit. The converter is a DC-DC conversion circuit that converts a DC voltage, for example, to a DC voltage of a different value. The converter is provided between the DC power supply 2 and the smoothing capacitor 6. The converter is configured to include, e.g., a reactor and the above-mentioned upper and lower arm circuit 10. This configuration can boost and/or suppress voltage. The power conversion device 4 may further include a filter capacitor for removing power supply noise from the DC power supply 2. The filter capacitor is provided between the DC power supply 2 and the converter.

### Configuration of Power Conversion Device:

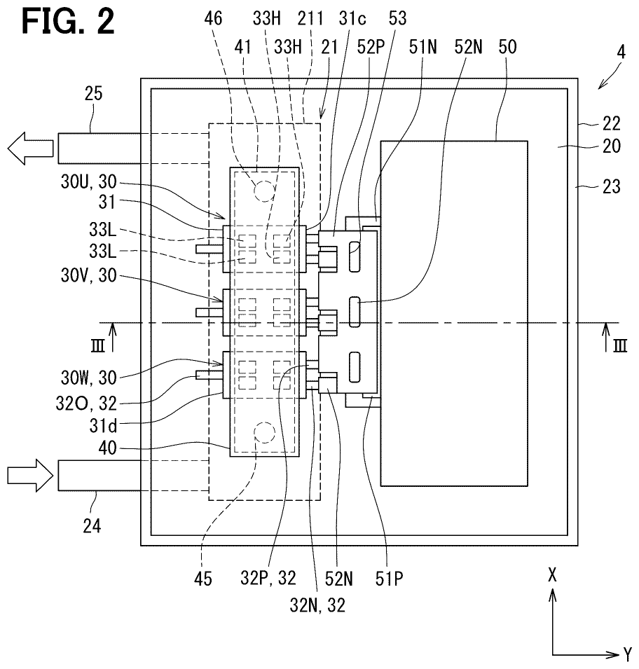

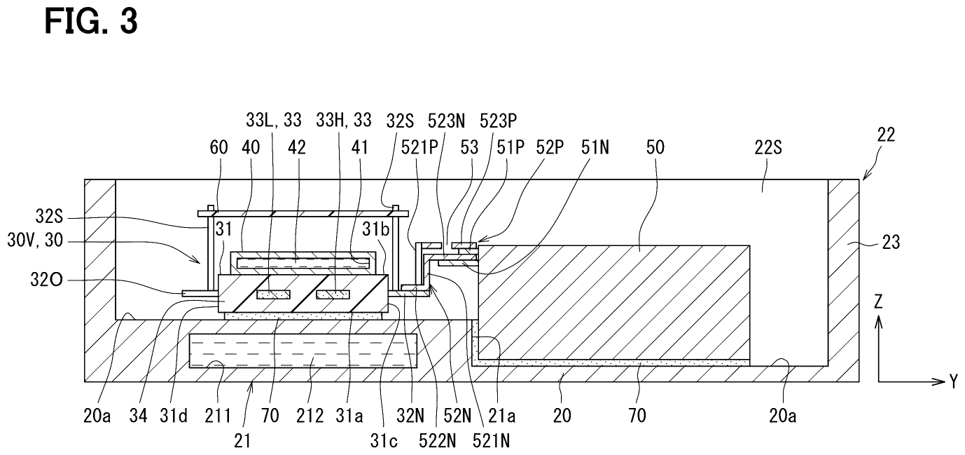

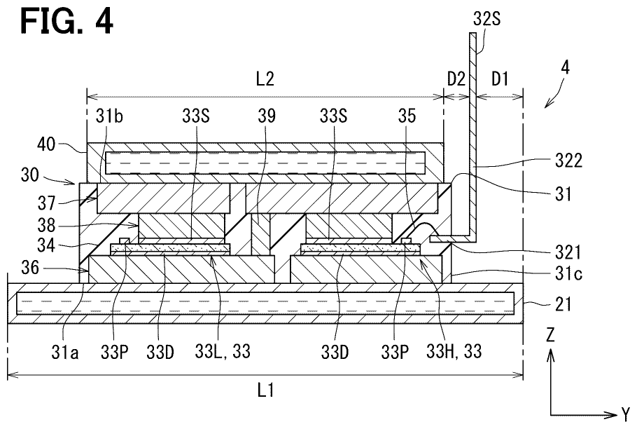

FIG. 2 is a plan view showing the power conversion device 4 of the present embodiment. In FIG. 2, the circuit board is omitted so that the arrangement of the semiconductor modules and the coolers can be seen. The white arrows in FIG. 2 indicate the direction in which the refrigerant flows. FIG. 3 is a cross-sectional view taken along a line Ill-Ill of FIG. 2. For convenience, FIG. 3 shows only the semiconductor element and the sealing body as the main body. Moreover, the portion of the external connection terminals sealed in the sealing body is omitted. FIG. 4 is a diagram showing the positional relationship between the signal terminals and the cooler. For convenience, FIG. 4 shows only the signal terminals on the upper arm side among the external connection terminals.

The power conversion device 4 of the present embodiment includes a base 20 having a first cooler 21, a semiconductor module 30, and a second cooler 40. The power conversion device 4 may include a capacitor 50. The power conversion device 4 may include a circuit board 60. As an example, the power conversion device 4 of the present embodiment includes the base 20 having the first cooler 21, the plurality of semiconductor modules 30, the second cooler 40, the capacitor 50, and the circuit board 60.

In the following description, the direction in which the semiconductor modules 30 are arranged is defined as the X direction. The Z direction is perpendicular to the X direction and is the stacking direction of the first cooler 21, the semiconductor module 30, and the second cooler 40. The direction perpendicular to both the X direction and the Z direction is defined as the Y direction. The Y direction corresponds to one direction perpendicular to the stacking direction. The X direction, the Y direction, and the Z direction are in a positional relationship orthogonal to each other. The plan view from the Z direction may be simply referred to as a plan view. When describing the relative positions of two members, the position of the member closer to the base 20 in the Z direction may be referred to as the lower position, and the position of the member farther from the base 20 may be referred to as the upper position. First, the schematic configuration of each element will be described.

### Base and First Cooler:

The base 20 has a semiconductor module 30 mounted on one surface 20a thereof. The base 20 is a support member that supports the semiconductor module 30. As an example, in the present embodiment, the semiconductor module 30 and the capacitor 50 are disposed on one surface of the base 20. The base 20 is made of a metal material such as aluminum.

The base 20 has the first cooler 21. The first cooler 21 is configured by utilizing the base 20. The first cooler 21 is a cooling section in the base 20. The first cooler 21 may be provided with a flow path through which a refrigerant flows, or may be a heat dissipation member provided with a heat sink or heat dissipation fins. As an example, the first cooler 21 of the present embodiment is configured to include a flow path 211 formed inside the base 20 and a surrounding portion of the flow path 211 in the base 20, as shown in FIGS. 2 and 3. The refrigerant 212 flows through the flow path 211. Available examples of the refrigerant 212 include a phase-changing refrigerant such as water or ammonia, and a non-phase-changing refrigerant such as ethylene glycol. The first cooler 21 cools the semiconductor module 30 from the rear surface 31b side.

The flow path 211 is provided so as to overlap at least a portion of each of the semiconductor modules 30 in the plan view in order to effectively cool the semiconductor modules 30. As an example, the flow path 211 in the present embodiment is provided so as to enclose most of each of the semiconductor modules 30 in the plan view. The flow path 211 extends along the arrangement direction of the three semiconductor modules 30, that is, along the X direction. The flow path 211 extends in the X direction.

The base 20 having the first cooler 21 may be formed of a single member, or may be formed by combining a plurality of members. The base 20 may be formed, for example, by combining two members, or may be formed by combining three or more members. The base 20 may be configured by combining a plurality of members in one portion and by a single member in the other portion. The first cooler 21 may be formed from a single member, for example, by a die casting method, or may be formed by combining a plurality of members. The base 20 may have a structure in which the first cooler 21, which is formed by combining two members, is locally disposed on a single member, for example. For convenience, the base 20 is illustrated in a simplified manner in FIG. 3.

The surface 20a of the base 20 may be flat or may have projections and recesses. As an example, in the present embodiment, the capacitor mounting portion of the surface 20a is recessed with respect to the semiconductor module mounting portion.

The base 20 may be provided as a standalone base 20 or may be provided as part of a case that houses other elements of the power conversion device 4. As an example, the base 20 in the present embodiment is provided as a bottom wall of the case 22. The case 22 has an opening to accommodate other elements. The case 22 has the base 20 forming a bottom wall, and a side wall 23 that is connected to the base 20 and defines an accommodation space 22S together with the base 20. As an example, the case 22 in the present embodiment has a box shape with one side open. The case 22 has a substantially rectangular shape when viewed in a plan view in the Z direction. In the accommodation space 22S of the case 22, a semiconductor module 30, a second cooler 40, a capacitor 50, a circuit board 60, etc. are arranged.

An inlet pipe 24 for supplying refrigerant to the first cooler 21 and the second cooler 40, and an outlet pipe 25 for discharging the refrigerant from the first cooler 21 and the second cooler 40 are attached to the side wall 23. The inlet pipe 24 and the outlet pipe 25 are inserted through corresponding through holes (not shown) and are arranged inside and outside the case 22. Each of the inlet pipe 24 and the outlet pipe 25 includes a portion extending in the Y direction. The inlet pipe 24 and the outlet pipe 25 are attached to a common side wall 23, for example.

The power conversion device 4 may include a cover (lid) (not shown) that closes the opening of the case 22. The case 22 and the cover are sometimes referred to as a housing.

### Semiconductor Module:

The semiconductor module 30 constitutes the upper and lower arm circuits 10 described above, that is, the inverter 5. The power conversion device 4 of the present embodiment includes three semiconductor modules 30. One semiconductor module 30 provides one series circuit 12, that is, the upper and lower arm circuits 10 for one phase. The plurality of semiconductor modules 30 include a semiconductor module 30U constituting the upper and lower arm circuits 10U, a semiconductor module 30V constituting the upper and lower arm circuits 10V, and a semiconductor module 30W constituting the upper and lower arm circuits 10W.

All the semiconductor modules 30 have a common structure. Each semiconductor module 30 includes a main body 31 and external connection terminals 32 protruding from the main body 31. The main body 31 includes a semiconductor element 33, a sealing body 34, and the like.

The semiconductor element 33 includes a switching element formed on a semiconductor substrate which is made of a material such as silicon (Si), a wide bandgap semiconductor having a wider bandgap than silicon, or the like. The switching element has a vertical structure so that the main current flows in the thickness direction of the semiconductor substrate. Examples of the wide bandgap semiconductor include silicon carbide (SiC), gallium nitride (GaN), gallium oxide (Ga2O3), and diamond. The semiconductor element 33 may be referred to as a power element or a semiconductor chip.

As an example, the semiconductor element 33 of the present embodiment is configured by forming the above-mentioned n-channel type MOSFET 13 and FWD 14 on a semiconductor substrate made of SiC. The MOSFET 13 has a vertical structure so that a main current flows in the thickness direction of the semiconductor element 33 (semiconductor substrate). The semiconductor element 33 has main electrodes on both sides in the thickness direction of the semiconductor element 33. Specifically, as shown in FIG. 4, each of the semiconductor elements 33 has a drain electrode 33D on one surface and a source electrode 33S on the back surface. The drain electrode 33D corresponds to a first main electrode, and the source electrode 33S corresponds to a second main electrode. The drain electrode 33D is formed over almost the entire area of one surface. The source electrode 33S is formed on a part of the back surface. Hereinafter, the drain electrode 33D and the source electrode 33S may be referred to as main electrodes 33D and 33S.

The main current flows between the drain electrode 33D and the source electrode 33S. The semiconductor element 33 has a pad 33P, which is an electrode for signals, on the back surface on which the source electrode 33S is formed. The semiconductor element 33 is arranged so that its thickness direction is substantially parallel to the Z-direction. The semiconductor element 33 of the present embodiment includes two semiconductor elements 33H that provide switching elements on the high side of the series circuit 12 and two semiconductor elements 33L that provide switching elements on the low side of the series circuit 12. The semiconductor elements 33H and 33L are arranged side by side in the Y direction. The two semiconductor elements 33H are arranged side by side in the X direction. Similarly, the two semiconductor elements 33L are arranged side by side in the X direction.

The four semiconductor elements 33 provide the four switching elements of one series circuit 12. The semiconductor module 30 includes semiconductor elements 33 whose number corresponds to the number of switching elements that constitute one series circuit 12. When the number of switching elements constituting the series circuit 12 is two, the semiconductor module 30 includes one each of the semiconductor elements 33H and 33L.

The sealing body 34 encapsulates and seals a part of other elements constituting the semiconductor modules 30. The rest of the other components are exposed to the outside of the sealing body 34. The sealing body 34 seals the semiconductor element 33, a portion of each of the external connection terminals 32, and the like. The other portion of each of the external connection terminals 32 protrudes outside the sealing body 34. The sealing body 34 includes, for example, resin. The sealing body 34 is molded by, e.g., a transfer molding method using resin as an epoxy material. The sealing body 34 has, for example, a substantially rectangular shape in the plan view. The sealing body 34 forms the outer shell of the main body 31.

The sealing body 34, i.e., the main body 31, has one surface 31a as a surface forming an outer shell, and the rear surface 31b that is the surface opposite to the one surface 31a in the Z direction. The one surface 31a and the rear surface 31b are, for example, flat surfaces. The sealing body 34 also has side surfaces 31c and 31d which connect the one surface 31a and the rear surface 31b. The side surface 31c is the surface opposite to the side surface 31d in the Y direction.

The multiple external connection terminals 32 include main terminals 32P, 32N, 32O electrically connected to main electrodes 33D, 33S of the semiconductor element 33, and a signal terminal 32S electrically connected to a pad 33P. The main terminal 32P is electrically connected to a drain electrode 33D of the semiconductor element 33H. The main terminal 32N is electrically connected to a source electrode 33S of the semiconductor element 33L. The main terminal 32P may be referred to as a P-terminal, a high potential power supply terminal, a positive terminal, or the like. The main terminal 32N may be referred to as an N-terminal, a low potential power supply terminal, a negative terminal, or the like. The main terminals 32P, 32N are electrically connected to a capacitor 50, that is, a smoothing capacitor 6. The main terminals 32P, 32N protrude outward from a side surface 31c of the main body 31. The protruding portions of the main terminals 32P, 32N are arranged side by side in the X direction.

The main terminal 32O is electrically connected to a connection point between the source electrode 33S of the semiconductor element 33H and the drain electrode 33D of the semiconductor element 33L, that is, the connection point (midpoint) of the series circuit 12. The main terminal 32O protrudes outward from a side surface 31d of the main body 31. The main terminal 32O may be referred to as an O terminal, an output terminal, an AC terminal, or the like. The main terminal 32O is connected to a corresponding winding 3a of the motor generator 3, for example, via a bus bar (not shown).

The signal terminal 32S protrudes to the outside from the main body 31 (sealing body 34). For example, a signal terminal 32S connected to the pad 33P of the semiconductor element 33H protrudes from a side surface 31c of the main body 31. Although not shown, the signal terminal 32S connected to the pad 33P of the semiconductor element 33L protrudes from the side surface 31d.

The main body 31 of the semiconductor module 30 includes, in addition to the above-mentioned elements, a bonding wire 35, wiring members 36 and 37, a conductive spacer 38, and a joint member 39. These elements are wiring elements that electrically connect the semiconductor element 33 and the external connection terminals 32. The bonding wire 35 electrically connects the signal terminal 32S to the corresponding pad 33P.

The wiring members 36 and 37 provide a wiring function for electrically connecting the main electrodes 33D and 33S of the semiconductor element 33 to the main terminals 32P, 32N, and 32O. The wiring member 36 is electrically connected to the drain electrodes 33D of the semiconductor elements 33H and 33L. The source electrodes 33S of the semiconductor elements 33H and 33L are electrically connected to the wiring member 37 via the conductive spacer 38. The wiring members 36 and 37 provide a heat dissipation function for dissipating heat from the semiconductor element 33. The wiring members 36 and 37 are disposed so as to sandwich the semiconductor element 33 in the Z direction.

The wiring members 36 and 37 may be, for example, a heat sink which is a metal member, or may be a substrate in which metal bodies are disposed on both sides of an insulating base material. The heat sink may be configured as part of the lead frame. The wiring member 36 is patterned so as to electrically separate the semiconductor element 33H from the semiconductor element 33L. The wiring member 37 is patterned so as to electrically separate the semiconductor element 33H from the semiconductor element 33L. Although not shown, the wiring portion of the wiring member 37 connected to the source electrode 33S of the semiconductor element 33L extends toward the side surface 31c in the Y direction in a cross section different from that in FIG. 4. As a result, the main terminal 32N is disposed on the side surface 31c side.

The wiring members 36 and 37 may be entirely sealed by the sealing body 34, or may be partially exposed from at least one of the one surface 31a and the rear surface 31b of the main body 31. As an example, in the present embodiment, the surface of the wiring member 36 opposite the semiconductor element 33 is exposed from the one surface 31 a, and the surface of the wiring member 37 opposite the semiconductor element 33 is exposed from the rear surface 31b. Accordingly, heat dissipation properties can be enhanced.

The conductive spacer 38 ensures a predetermined space between the source electrode 33S and the wiring member 37. The conductive spacer 38 is interposed between the semiconductor element 33 and the wiring member 37 in order to secure a space for connecting the bonding wire 35 to the pad 33P. The conductive spacers 38 are disposed individually for each of the semiconductor elements 33. The joint member 39 electrically connects the wiring portion of the wiring member 37 connected to the source electrode 33S of the semiconductor element 33H and the wiring portion of the wiring member 37 connected to the drain electrode 33D of the semiconductor element 33L.

The semiconductor module 30 is disposed on the first cooler 21 so that the one surface 31a of the main body 31, that is, the surface on which the drain electrode 33D of the semiconductor element 33 is formed, faces the one surface 20a of the base 20. A thermally conductive member may be disposed between the semiconductor module 30 and the first cooler 21. As an example, in the present embodiment, a thermally conductive member 70 is interposed between the semiconductor module 30 and the first cooler 21. The thermally conductive member 70 transfers heat from the semiconductor module 30, for example, heat generated by the semiconductor element 33, to the first cooler 21. The thermally conductive member 70 has electrical insulation properties. As an example, the thermally conductive member 70 in the present embodiment is a thermally conductive grease. A thermally conductive gel may be used instead of the thermally conductive grease. The thermally conductive member 70 is sometimes referred to as a TIM. The TIM is an abbreviation for Thermal Interface Material.

As shown in FIG. 2, the three semiconductor modules 30 are aligned in the X direction. In other words, the multiple semiconductor modules 30 are arranged side by side along the X direction. As an example, in the present embodiment, the three semiconductor modules 30 are arranged in the order of semiconductor module 30U, semiconductor module 30V, and semiconductor module 30W. In addition, in the X direction, the side surfaces of adjacent semiconductor modules 30 face each other with a predetermined gap therebetween. Specifically, a side surface of the semiconductor module 30U faces a side surface of the semiconductor module 30V. A side surface of the semiconductor module 30V and a side surface of the semiconductor module 30W face each other.

### Second Cooler:

The second cooler 40 is provided without using the base 20 (case 22). The second cooler 40 is disposed on the rear surface 31b of the semiconductor module 30. The second cooler 40 is stacked on the main body 31 of the semiconductor module 30 on the opposite side to the first cooler 21 so as to face the surface on which the source electrode 33S of the semiconductor element 33 is formed. The above-mentioned thermally conductive member 70 may be disposed between the second cooler 40 and the semiconductor module 30. The second cooler 40 cools the semiconductor module 30 from the opposite side to the first cooler 21 in the Z direction. The second cooler 40 and the first cooler 21 can cool the semiconductor module 30 from both sides in the Z direction.

The second cooler 40 has a flow path 41 therein. As an example, in the present embodiment, a refrigerant 42 is supplied to the flow path 41 via an inlet pipe 24. The refrigerant 42 that has flowed through the flow path 41 is discharged to the outside of the power conversion device 4 via the outlet pipe 25. The second cooler 40 is disposed in the accommodation space 22S of the case 22. The refrigerant 42 is the same as the refrigerant 212 described above.

As an example, the second cooler 40 in the present embodiment is thinner than the first cooler 21. The second cooler 40 is, for example, a tubular body having a flattened shape as a whole. The second cooler 40 is configured to have the flow path 41 therein, using, for example, a pair of plates (thin metal plates). At least one of the pair of plates is pressed into a shape that bulges in the Z-direction. After that, the outer peripheral edges of the pair of plates are fixed to each other by caulking or the like, and are joined to each other on the entire circumference by brazing or the like. As a result, the flow path 41 through which the refrigerant 42 can flow is formed between the pair of plates.

The flow path 41 is provided so as to overlap at least a portion of each of the semiconductor modules 30 in the plan view in order to effectively cool the semiconductor modules 30. The flow path 41 in the present embodiment is provided so as to overlap most of each of the semiconductor modules 30 in the plan view. The flow path 41 extends along the arrangement direction of the three semiconductor modules 30, that is, along the X direction. The flow path 41 extends in the X direction. The flow path 41 crosses the three semiconductor modules 30 in the X direction. In the plan view, the flow path 41 is contained within the flow path 211. The extension length of the flow path 41 is shorter than the extension length of the flow path 211.

The second cooler 40 is stacked and disposed on the first cooler 21 with the semiconductor module 30 interposed therebetween. The second cooler 40 may be pressed in the Z direction from the surface opposite to the semiconductor module 30 by a pressing member (not shown). By applying pressure, good thermal conduction is maintained between the second cooler 40 and the semiconductor module 30, and between the semiconductor module 30 and the first cooler 21, respectively. The pressure member may include, for example, a pressure plate and an elastic member. The elastic member is, e.g., a material that generates a pressing force by elastic deformation of rubber, or a metal spring. The elastic member is disposed between the pressure plate and the second cooler 40 in the Z direction. By fixing the pressure plate at a predetermined position relative to the case 22, the elastic member is elastically deformed. The reaction force of the elastic deformation presses the second cooler 40 and the semiconductor module 30 against the first cooler 21 (base 20).

The second cooler 40 is connected to the first cooler 21 via the connecting pipes 45 and 46. The connecting pipe 45 is connected to the vicinity of one end of the second cooler 40 in the X direction, specifically, to the vicinity of the end portion closer to the inlet pipe 24. The connecting pipe 46 is connected to the vicinity of the other end of the second cooler 40, specifically, to the vicinity of the end portion closer to the outlet pipe 25. The two connecting pipes 45 and 46 are disposed in the X direction between the connecting position of the inlet pipe 24 and the first cooler 21 and the connecting position of the outlet pipe 25 and the first cooler 21.

A part of the refrigerant supplied from the inlet pipe 24 flows through the flow path 211 as the refrigerant 212 and is discharged from the outlet pipe 25. The other part of the refrigerant is supplied to the flow path 41 through the flow path 211 and the flow path of the connecting pipe 45. The refrigerant 42 that has flowed through the flow path 41 flows into the flow path 211 through the flow path of the connecting pipe 46 and is discharged from the outlet pipe 25. The flow rate of the refrigerant 212 flowing through the flow path 211 is greater than the flow rate of the refrigerant 42 flowing through the flow path 41. The flow path 211 is a main flow path, and the flow path 41 is a sub-flow path branched off from the flow path 211.

### Capacitor:

The capacitor 50 constitutes the smoothing capacitor 6 described above. The capacitor 50 corresponds to a capacitor component. The capacitor 50 includes, for example, a case (not shown) and a capacitor element housed in the case. FIGS. 2 and 3 illustrates the capacitor 50 in a simplified manner.

As an example, the capacitor element of the present embodiment is a film capacitor element. The capacitor element is formed, for example, by winding a film around the axis in the Z direction. The capacitor element has electrodes (not shown) on both end surfaces in the Z direction thereof. The electrodes are sometimes referred to as metallikon. The capacitor 50 has a P-terminal 51P connected to the positive electrode, and an N-terminal 51N connected to the negative electrode.

The P-terminal 51P and the N-terminal 51N are plate-shaped metal members. The P-terminal 51P and the N-terminal 51N are connected to corresponding electrodes by soldering, resistance welding, laser welding, or the like. The P-terminal 51P and the N-terminal 51N may be referred to as a capacitor bus bar or the like. FIGS. 2 and 3 illustrates the connection portions of the P-terminal 51P and the N-terminal 51N with the corresponding main terminals 32P, 32N. The P-terminal 51P and the N-terminal 51N have a connection portion (not shown) for electrically connecting the smoothing capacitor 6 and the DC power supply 2.

The capacitor 50 is disposed on the one surface 20a of the base 20 that constitutes the first cooler 21. The capacitor 50 of the present embodiment is disposed in the accommodation space 22S of the case 22. The capacitors 50 are arranged side by side in the Y direction with respect to the semiconductor module 30. The capacitor 50 has a generally rectangular shape in the plan view with its longitudinal direction aligned in the X direction.

The connection portion of the P-terminal 51P and the connection portion of the N-terminal 51N are extended toward the semiconductor module 30 in the Y direction. The connection portion of the P-terminal 51P and the connection portion of the N-terminal 51N are arranged such that their plate surfaces face each other in order to reduce inductance. The connection portion of the P-terminal 51P and the connection portion of the N-terminal 51N have different extension lengths in the Y direction so as to enable connection to the P-bus bar 52P and the N-bus bar 52N. As an example, in the present embodiment, the connection portion of the N-terminal 51N is located below the connection portion of the P-terminal 51P. The connection portion of the N-terminal 51N is longer in the Y direction than the connection portion of the P-terminal 51P.

As an example, in the present embodiment, the thermally conductive member 70 is interposed between the capacitor 50 and the one surface 20a of the base 20. The capacitor 50 is disposed at a position that does not overlap with the first cooler 21 in the plan view. As described above, the mounting position of the capacitor 50 on the base 20 is recessed with respect to the mounting position of the semiconductor module 30. As an example, in the present embodiment, a side surface of the capacitor 50 is in indirect contact with the side surface 21 a of the first cooler 21 via the thermally conductive member 70. Furthermore, the bottom surface of the capacitor 50 is in indirect contact with a portion of the base 20 adjacent to the first cooler 21 via the thermally conductive member 70. The contact surface of the capacitor 50 with the base 20 is substantially flat. In this manner, the capacitor 50 is thermally connected to the base 20, and in particular to the first cooler 21.

The capacitor 50 further includes a P-bus bar 52P and an N-bus bar 52N. The P-bus bar 52P and the N-bus bar 52N are plate-shaped metal members. The P-bus bar 52P and the N-bus bar 52N are held in a predetermined positional relationship. The P-bus bar 52P and the N-bus bar 52N may be held in a predetermined positional relationship by, for example, an insulating member (not shown). The P-bus bar 52P and the N-bus bar 52N are arranged so that their plate surfaces face each other over most of their entire length in order to reduce inductance. The P-bus bar 52P electrically connects the main terminal 32P of the semiconductor module 30 and the P-terminal 51P of the capacitor 50. The N-bus bar 52N electrically connects the main terminal 32N of the semiconductor module 30 and the N-terminal 51N of the capacitor 50.

As an example, the P-bus bar 52P in the present embodiment has a base portion 521P extending in the Z direction, and extension portions 522P and 523P extending in the Y direction from both ends of the base portion 521P. For convenience, the extension portion 522P is not shown in the figure, but has the same configuration as an extension portion 522N described below. The extension portion 522P extends in the Y direction from the lower end of the base portion 521P toward the semiconductor module 30. The extension portion 522P is connected to the main terminal 32P. The extension portion 523P extends in the Y direction from the upper end of the base portion 521P toward the capacitor 50. The extension portion 523P is connected to the P-terminal 51P.

Similarly, the N-bus bar 52N has a base portion 521N extending in the Z direction, and extension portions 522N, 523N extending in the Y direction from both ends of the base portion 521N. The extension portion 522N extends in the Y direction from the lower end of the base portion 521N toward the semiconductor module 30. The extension portion 522N is connected to the main terminal 32N. The extension portion 523N extends in the Y direction from the upper end of the base portion 521N toward the capacitor 50. The extension portion 523N is connected to the N-terminal 51N.

The P-bus bar 52P and the N-bus bar 52N can be connected to the corresponding main terminals 32P, 32N and terminals 51P, 51N by soldering, resistance welding, laser welding, or the like. As an example, in the present embodiment, the P-bus bar 52P and the N-bus bar 52N are connected to the corresponding P-terminal 51P and N-terminal 51N by laser welding. In order to enable laser welding, the extension portion 523P being the upper layer has a through hole 53. The through hole 53 is an opening provided for laser welding the extension portion 523N, which is the lower layer. The number of through holes 53 may be one or more. As an example, the P-bus bar 52P in the present embodiment has three through holes 53. The three through holes 53 are provided at a predetermined pitch in the X direction as shown in FIG. 2.

### Circuit Board:

Although not shown, the circuit board 60 includes a wiring board in which wiring is arranged on an insulating base material such as resin, electronic components mounted on the wiring board, connectors, and the like. The circuit is composed of mounted electronic components and wiring. The above-described circuit board 60 is configured on the drive circuit 7.

The circuit board 60 is disposed so as to overlap the semiconductor module 30 in the plan view in the Z direction. The circuit board 60 is disposed above the three semiconductor modules 30. The signal terminals 32S of the three semiconductor modules 30 are mounted on the circuit board 60. As an example, the circuit board 60 in the present embodiment is disposed in the accommodation space 22S of the case 22. The circuit board 60 is located above the second cooler 40.

### Arrangement of Signal Terminal and Cooler:

For convenience, FIG. 4 shows only the signal terminal 32S of the external connection terminals 32 that is drawn out of the sealing body 34 from the side surface 31c of the body 31, that is, the side surface shared with the main terminals 32P and 32N. FIG. 4 shows the positional relationship between the signal terminal 32S, the first cooler 21, and the second cooler 40.

As shown in FIG. 4, the signal terminal 32S is a bent terminal. The signal terminal 32S has a first extension portion 321 and a second extension portion 322. The first extension portion 321 includes a portion of the signal terminal 32S that is connected to the bonding wire 35. The first extension portion 321 extends in the Y direction. A part of the first extension portion 321 is sealed by the sealing body 34, and another part thereof protrudes to the outside from the side surface 31c. The first extension portion 321 extends toward the capacitor 50.

The second extension portion 322 is continuous with the first extension portion 321. The second extension portion 322 is bent with respect to the first extension portion 321 and extends in the Z direction. The second extension portion 322 extends upward from an end portion of the first extension portion 321. The second extension portion 322 faces the second cooler 40 in the Y direction.

Here, the length of the first cooler 21 in the Y direction is defined as L1, and the length of the second cooler 40 in the Y direction is defined as L2. In addition, in the Y direction, a distance between the second extension portion 322 of the signal terminal 32S and the end of the first cooler 21 on the capacitor 50 side is defined as D1, and a distance between the second extension portion 322 and the end of the second cooler 40 on the capacitor 50 side is defined as D2. The power conversion device 4 is configured so that the lengths L1, L2 and the distances D1, D2 satisfy the following relationships.

As shown in FIG. 4, the length L2 of the second cooler 40 is shorter than the length L1 of the first cooler 21. Furthermore, the distance D2 is shorter than the distance D1. As an example, the first cooler 21 in the present embodiment is longer than the main body 31 of the semiconductor module 30 in the Y direction. The first cooler 21 protrudes outward beyond the side surface 31c. The second cooler 40 is shorter than the main body 31 in the Y direction. The second cooler 40 is recessed with respect to the side surface 31c.

### Summary of First Embodiment

According to the power conversion device 4 of the present embodiment, the length L2 of the second cooler 40 in the Y direction is shorter than the length L1 of the first cooler 21. Furthermore, the distance D2 between the second extension portion 322 of the signal terminal 32S, which is a bent terminal, and the second cooler 40 is shorter than the distance D1 between the second extension portion 322 and the first cooler 21. In this way, the second cooler 40 is made shorter than the first cooler 21 in the Y direction, and the second extension portion 322 of the signal terminal 32S (bent terminal) is brought closer to the second cooler 40. This allows the capacitor 50 (smoothing capacitor 6) to be located close to the main body 31 of the semiconductor module 30 while avoiding interference with the signal terminal 32S. Therefore, the inductance of the wiring connecting the semiconductor element 33 and the capacitor 50 can be reduced.

As described above, since the second extension portion 322 of the signal terminal 32S is located closer to the second cooler 40, the size of the power conversion device 4 in the Y direction can be reduced. In addition, the first cooler 21 on the drain electrode 33D side is made longer, and the second cooler 40 on the source electrode 33S side is made shorter. In other words, the length is increased on the first cooler 21 side, which has a large electrode area and a short heat transfer path from the electrode to the cooler. Therefore, it is possible to ensure heat dissipation even while shortening the second cooler 40.

The signal terminal 32S is required to at least satisfy the above-mentioned relationship D2<D1. As an example, the signal terminal 32S in the present embodiment protrudes outside the sealing body 34 from the common side surface 31c together with the main terminals 32P and 32N. The signal terminal 32S is bent outside the sealing body 34. In this configuration, the signal terminal 32S satisfies the above-mentioned relationship D2<D1. In other words, the second extension portion 322 is brought closer to the side surface 31c. Therefore, the capacitor 50 can be disposed close to the main body 31.

The length L1 of the first cooler 21 only needs to be longer than the length L2 of the second cooler 40. In the Y direction, the first cooler 21 may have a length substantially equal to that of the main body 31, or may have a length shorter than that of the main body 31. As an example, in the present embodiment, the first cooler 21 is longer than the main body 31 in the Y direction. The first cooler 21 protrudes from the side surface 31c of the main body 31. The main terminals 32P, 32N face a portion of the base 20 that constitutes the first cooler 21 in the Z direction. In other words, the main terminals 32P, 32N and the first cooler 21 face each other. The inductance can be further reduced by the magnetic flux cancellation effect due to eddy currents generated in the base 20. Moreover, the heat dissipation properties of the semiconductor module 30 can be improved.

In particular, since the plate surfaces of the main terminals 32P, 32N face the base 20, the effect of reducing inductance can be enhanced. In addition, the P-us bar 52P and the N-bus bar 52N also face the portion of the base 20 that constitutes the first cooler 21 in the Z direction. Therefore, the inductance can be further reduced. Since the plate surfaces of the P-bus bar 52P and the N-bus bar 52N face the base 20, the effect of reducing inductance can be enhanced.

The arrangement of the main terminals 32P, 32N, and 32O is not particularly limited. For example, the main terminals 32P, 32N, and 32O may be configured to protrude from a common surface of the main body 31. As an example, in the present embodiment, the main terminals 32P, 32N connected to the capacitor 50 protrude from the side surface 31c of the main body 31, and the main terminal 32O connected to motor generator 3 protrudes from the side surface 31d. In this manner, the main terminal 32O protrudes from a different surface from the main terminals 32P and 32N. This simplifies the layout of the wiring connecting the main terminals 32P, 32N to the capacitor 50, and reduces the inductance. Furthermore, by providing the main terminal 32P, which is a positive terminal, and the main terminal 32N, which is a negative terminal, side by side, it is possible to reduce inductance.

The power conversion device 4 may be configured without including the capacitor 50. For example, the base 20 may have only the portion that constitutes the first cooler 21. As an example, the power conversion device 4 of the present embodiment includes the capacitor 50 that provides the smoothing capacitor 6. Therefore, in a configuration including the capacitor 50, the above-mentioned effects can be achieved. The capacitor 50 is a heat-generating component that generates heat when current is applied thereto. The capacitor 50 is aligned with the semiconductor module 30 in the Y direction. The capacitor 50 is in contact with the base 20 via a thermally conductive member 70. In this manner, since the capacitor 50 is thermally connected to the base 20, the heat of the capacitor 50 can be dissipated to the base 20. Therefore, the size of the capacitor 50 can be reduced, and therefore the size of the power conversion device 4 can be reduced.

In particular, in the present embodiment, the side surface of the capacitor 50 is in contact with the side surface 21 a of the first cooler 21 via the thermally conductive member 70. Therefore, the heat generated in the capacitor 50 can be effectively released, that is, the capacitor 50 can be effectively cooled. Since the portion of the base 20 on which the capacitor 50 is mounted is recessed, the size of the power conversion device 4 in the Z direction can be reduced, that is, the height can be reduced. Furthermore, the bottom surface of the capacitor 50 is in contact with a portion of the base 20 adjacent to the first cooler 21 via the thermally conductive member 70. This also allows the heat generated by the capacitor 50 to be dissipated effectively.

The arrangement of the semiconductor element 33 is not particularly limited. In the Z direction, the semiconductor element 33 may be disposed near the center of the main body 31 or may be disposed biased toward the second cooler 40. As an example, the semiconductor element 33 in the present embodiment is disposed at a position closer to the first cooler 21 than the second cooler 40 in the Z direction. The semiconductor element 33 is arranged biased toward the first cooler 21 side. This makes it possible to reduce the thermal resistance between the first cooler 21, which has a long length L1, and the semiconductor element 33. Therefore, heat dissipation properties can be enhanced.

### Modification

Although an example has been shown in which the capacitor 50, which is a heat-generating component, is indirectly in contact with the base 20, the present disclosure is not limited to this configuration. The capacitor 50 may be configured to be in direct contact with the base 20 without the thermally conductive member 70 therebetween. A portion of the capacitor 50 may be disposed on the first cooler 21.

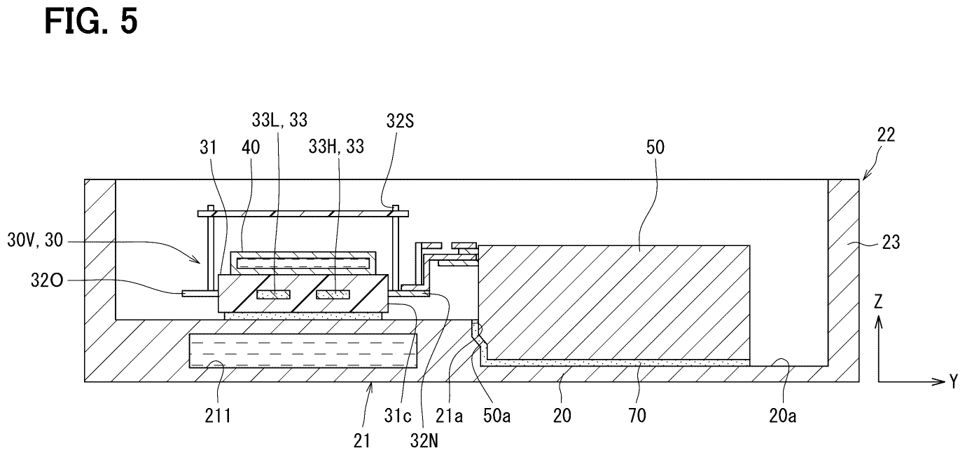

Although an example has been shown in which the contact surface of the capacitor 50 with the base 20 is substantially flat, the present disclosure is not limited to this configuration. For example, as shown in FIG. 5, the side surface 50a of the capacitor 50 may have projections and recesses. By providing the contact surface with projections and recesses in this manner, the contact area can be increased, and heat dissipation can be improved. In FIG. 5, the side surface 21a of the first cooler 21 has a shape with projections and recesses following the side surface 50a. This can prevent the thermally conductive member 70 from becoming thicker locally. In addition, the side surface 21a may be a substantially flat surface, while the side surface 50a has projections and recesses. The bottom surface of the capacitor 50 may be provided with projections and recesses.

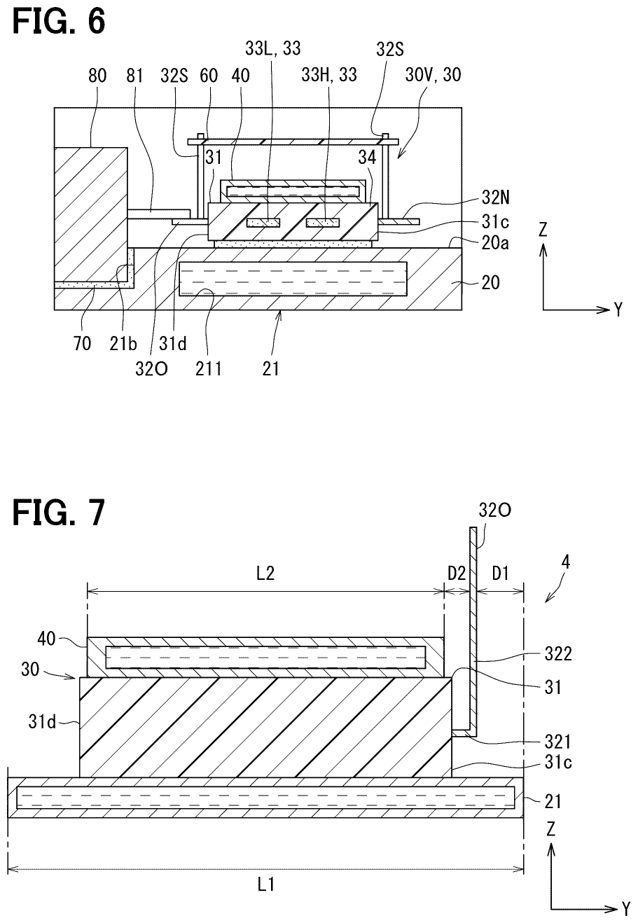

The heat generating component that directly or indirectly contacts the base 20 is not limited to the capacitor 50. For example, as shown in FIG. 6, a current sensor 80 for detecting a phase current may be used as the heat generating component. The current sensor 80 detects the current flowing through an O-bus bar 81, which is a wiring that connects the main terminal 32O and the winding 3a. As an example, in FIG. 6, the side surface of the current sensor 80 is in contact with the side surface 21b of the first cooler 21 via the thermally conductive member 70. Therefore, the heat generated by the current sensor 80 can be effectively dissipated. Furthermore, the bottom surface of the current sensor 80 is in contact with a portion of the base 20 adjacent to the first cooler 21 via the thermally conductive member 70. This also enables the heat generated by the current sensor 80 to be dissipated effectively. The current sensor 80 may be configured to directly contact the base 20 without using the thermally conductive member 70. The power conversion device 4 may include both the capacitor 50 and the current sensor 80 as heat generating components.

### Second Embodiment

A second embodiment is a modification of the preceding embodiment as a basic configuration and may incorporate description of the precedent embodiments. In the previous embodiment, the signal terminal is provided as bent terminal. Alternatively, the output terminal may be provided as a bent terminal.

FIG. 7 shows the positional relationship between the main terminal 32O (output terminal), the first cooler 21, and the second cooler 40 in the power conversion device 4 according to the present embodiment. FIG. 7 corresponds to FIG. 4. For convenience, the main body 31 of the semiconductor module 30 is illustrated in a simplified manner in FIG. 7. Of the external connection terminals 32, only the main terminal 32O is shown.

As shown in FIG. 7, the main terminal 32O is a bent terminal. The main terminal 32O has a first extension portion 321 and a second extension portion 322, similar to the signal terminal 32S shown in the preceding embodiment. The first extension portion 321 includes a connection portion of the main terminal 32O that is connected to a connection point between the source electrode 33S of the semiconductor element 33H and the drain electrode 33D of the semiconductor element 33L. The first extension portion 321 is connected to a wiring member 37 to which the source electrode 33S of the semiconductor element 33H is electrically connected, for example. The first extension portion 321 extends in the Y direction. A part of the first extension portion 321 is sealed by the sealing body 34, and another part thereof protrudes to the outside from the side surface 31c. The main terminal 32O protrudes from the side surface 231c together with the main terminals 32P and 32O (not shown). The first extension portion 321 extends toward the capacitor 50.

The second extension portion 322 is continuous with the first extension portion 321. The second extension portion 322 is bent with respect to the first extension portion 321 and extends in the Z direction. The second extension portion 322 extends upward from an end portion of the first extension portion 321. The second extension portion 322 faces the second cooler 40 in the Y direction.

As shown in FIG. 7, the length L2 of the second cooler 40 is shorter than the length L1 of the first cooler 21. Furthermore, the distance D2 between the second extension portion 322 and the second cooler 40 is shorter than the distance D1 between the second extension portion 322 and the first cooler 21. As an example, the first cooler 21 in the present embodiment is longer than the main body 31 of the semiconductor module 30 in the Y direction. The first cooler 21 protrudes outward beyond the side surface 31c. The second cooler 40 is shorter than the main body 31 in the Y direction. The second cooler 40 is recessed with respect to the side surface 31c.

### Summary of Second Embodiment

According to the power conversion device 4 of the present embodiment, the second cooler 40 is made shorter than the first cooler 21 in the Y direction, and the second extension portion 322 of the main terminal 32O (bent terminal) is brought closer to the second cooler 40. This allows the capacitor 50 (smoothing capacitor 6) to be located close to the main body 31 of the semiconductor module 30 while avoiding interference with the main terminal 32O. Therefore, the inductance of the wiring connecting the semiconductor element 33 and the capacitor 50 can be reduced. Moreover, the size of the power conversion device 4 in the Y direction can be reduced. Even though the second cooler 40 is short, heat dissipation performance can be ensured.

The main terminal 32O (bent terminal) protruding from the side surface 31c can be combined with any of the configurations shown in the previous embodiments, except for the configuration that assumes the main terminal 32O protruding from the surface opposite the main terminals 32P, 32N. The bent terminal may be configured to include both the main terminal 32O shown in the present embodiment and the signal terminal 32S shown in the preceding embodiment.

### Third Embodiment

A second embodiment is a modification of the preceding embodiment as a basic configuration and may incorporate description of the precedent embodiments. In the previous embodiment, the bent terminals and the main terminals 32P, 32N protrude from the common side surface 31c. Alternatively, the bent terminal may be configured to protrude from the rear surface 31b on the second cooler 40 side.

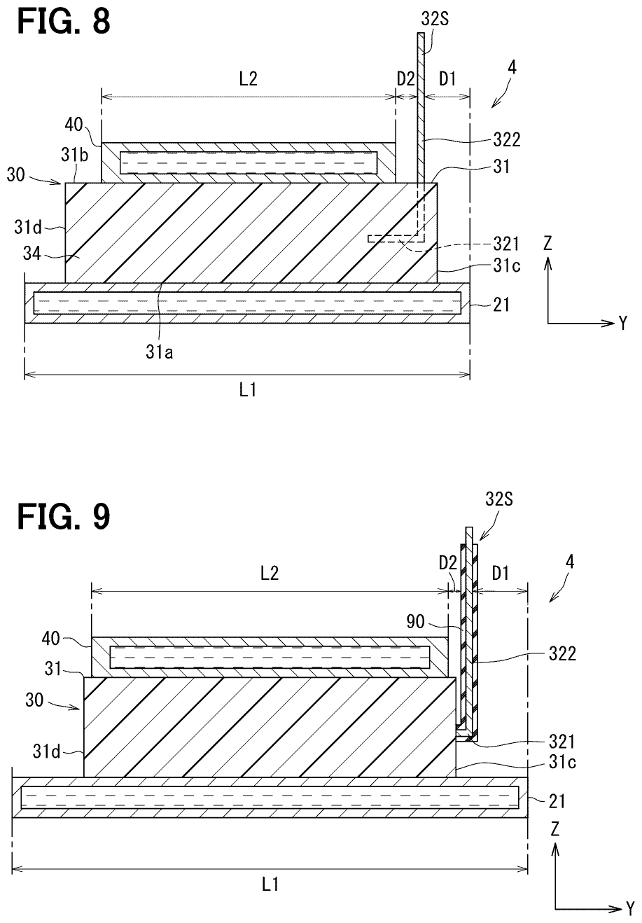

FIG. 8 shows the positional relationship between the signal terminal 32S, the first cooler 21, and the second cooler 40 in the power conversion device 4 according to the present embodiment. FIG. 8 corresponds to FIG. 4. As in FIG. 7, the main body 31 of the semiconductor module 30 is illustrated in a simplified manner in FIG. 8. Of the external connection terminals 32, only the signal terminal 32S on the upper arm side is shown.

The signal terminal 32S connected to the pad 33P of the semiconductor element 33H (not shown) protrudes from the rear surface 31b, not from the side surface 31c. The first extension portion 321 is sealed by the sealing body 34. A part of the second extension portion 322 is sealed by the sealing body 34, and another part of the second extension portion 322 protrudes outside the sealing body 34 from the rear surface 31b. The second extension portion 322 passes between an end surface of the wiring member 37 (not shown) (see FIG. 4) on the capacitor 50 side and the side surface 31c of the main body 31, and protrudes from the rear surface 31b. Other configurations are the same as those described in the preceding embodiments.

### Summary of Third Embodiment

As in the configurations described in the preceding embodiments, the power conversion device 4 of the present embodiment also satisfies the relationships L2<L1 and D2<D1. In other words, the second cooler 40 is made shorter than the first cooler 21 in the Y direction, and the second extension portion 322 of the signal terminal 32S (bent terminal) is brought closer to the second cooler 40. Therefore, the inductance of the wiring connecting the semiconductor element 33 and the capacitor 50 can be reduced. Moreover, the size of the power conversion device 4 in the Y direction can be reduced. Even though the second cooler 40 is short, heat dissipation performance can be ensured. In particular, the signal terminal 32S protruding from the rear surface 31b can be combined with the remaining configurations shown in the preceding embodiments, except for the configuration that assumes that the signal terminal 32S (bent terminal) protruding from the side surface 31c common to the main terminals 32P, 32N.

### Fourth Embodiment

A second embodiment is a modification of the preceding embodiment as a basic configuration and may incorporate description of the precedent embodiments. In the precedent embodiment, no other member was disposed between the second extension portion 322 of the bent terminal and the second cooler 40, and air is present between them. Alternatively, an insulating member may be disposed between the second extension portion 322 of the bent terminal and the second cooler 40.

FIG. 9 shows the positional relationship between the signal terminal 32S, the first cooler 21, and the second cooler 40 in the power conversion device 4 according to the present embodiment. FIG. 9 corresponds to FIG. 4. As in FIG. 7, the main body 31 of the semiconductor module 30 is illustrated in a simplified manner in FIG. 9. Of the external connection terminals 32, only the signal terminal 32S on the upper arm side is shown.

The signal terminal 32S is covered with an insulating member 90. The insulating member 90 is a coating resin. The insulating member 90 covers at least the portion of the signal terminal 32S that faces the second cooler 40 in the second extension portion 322 and the surrounding area thereof. As an example, the insulating member 90 in the present embodiment covers the signal terminal 32S except for the bonding wire 35 and the connection portion with the circuit board 60. The insulating member 90 is disposed between the second extension portion 322 and the second cooler 40 in the Y direction. Other configurations are the same as those described in the preceding embodiments.

### Summary of Fourth Embodiment

According to the power conversion device 4 of the present embodiment, since the insulating member 90 is interposed between the second extension portion 322 and the second cooler 40, the distance D2 between the second extension portion 322 and the second cooler 40 can be further narrowed. That is, the capacitor 50 can be brought even closer to the main body 31 of the semiconductor module 30. Therefore, the inductance can be further reduced. Moreover, the size of the power conversion device 4 in the Y direction can be reduced.

### Modification

Although the insulating member 90 is an example of a coating resin, the insulating member is not limited to this configuration. The insulating member 90 may be provided between the second extension portion 322 and the second cooler 40 by potting or the like. The insulating member 90 formed into a predetermined shape using an electrically insulating material may be fixed (for example, adhesively fixed) onto the rear surface 31b of the main body 31. In a configuration including the main terminal 32O as a bent terminal, the insulating member 90 may be provided between the second extension portion 322 and the second cooler 40. In a configuration in which the bent terminal protrudes from the rear surface 31b, the insulating member 90 may be provided between the second extension portion 322 and the second cooler 40.

### OTHER EMBODIMENTS

The disclosure in this specification and drawings is not limited to the exemplified embodiments. The disclosure encompasses the illustrated embodiments and modifications by those skilled in the art based thereon. For example, the disclosure is not limited to the combinations of components and/or elements shown in the embodiments. The disclosure may be implemented in various combinations. The disclosure may have additional portions that may be added to the embodiments. The disclosure encompasses omission of components and/or elements of the embodiments. The disclosure encompasses the replacement or combination of components and/or elements between one embodiment and another. The disclosed technical scope is not limited to the description of the embodiments. It should be understood that some disclosed technical ranges are indicated by description of claims, and includes every modification within the equivalent meaning and the scope of description of claims.

The disclosure in the specification, drawings and the like is not limited by the description of the claims. The disclosures in the specification, the drawings, and the like encompass the technical ideas described in the claims, and further extend to a wider variety of technical ideas than those in the claims. Therefore, various technical ideas can be extracted from the disclosure of the specification, the drawings and the like without being limited to the description of the claims.

When an element or a layer is described as “disposed above” or “connected”, the element or the layer may be directly disposed above or connected to another element or another layer, or an intervening element or an intervening layer may be present therebetween. In contrast, when an element or a layer is described as “disposed directly above” or “directly connected”, an intervening element or an intervening layer is not present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B.

Spatial relative terms “inside”, “outside”, “back”, “bottom”, “low”, “top”, “high”, etc. are used herein to facilitate the description that describes relationships between one element or feature and another element or feature. Spatial relative terms can be intended to include different orientations of a device in use or operation, in addition to the orientations depicted in the drawings. For example, when the device in the figure is flipped over, an element described as “below” or “directly below” another element or feature is directed “above” the other element or feature. Therefore, the term “below” can include both above and below. The device may be oriented in the other direction (rotated 90 degrees or in any other direction) and the spatially relative terms used herein are interpreted accordingly.

The vehicle drive system 1 is not limited to the above structure described in the embodiments. Although the present disclosure describes that one motor generator 3 is provided, it is not limited to the example described in the present disclosure. A plurality of motor generators may be provided.

Although the example in which the power conversion device 4 includes the inverter 5 as the power conversion circuit has been described, the present invention is not limited thereto. For example, a plurality of inverters may be provided. At least one inverter and a converter may be provided.

The number of semiconductor modules 30 is not limited to the above example. For example, one semiconductor module 30 may provide six arms 10H and 10L. One semiconductor module 30 may provide one arm, that is, one upper arm 10H or one lower arm 10L.

For example, the semiconductor module 30 may be configured to include one semiconductor element 33 that constitutes one arm. The main terminal connected to the drain electrode 33D of the semiconductor module 30 constituting the upper arm 10H is connected to the P-bus bar 52P. The main terminal connected to the source electrode 33S of the semiconductor module 30 constituting the lower arm 10L is connected to the N-bus bar 52N. The main terminal connected to the source electrode 33S of the semiconductor module 30 constituting the upper arm 10H and the main terminal connected to the drain electrode 33D of the semiconductor module 30 constituting the lower arm 10L are connected to the O-bus bar 81.

The power conversion device 4 may include at least the base 20 having the first cooler 21, the semiconductor module 30, and the second cooler 40. The power conversion device 4 may be configured so as to exclude the capacitor 50. The power conversion device 4 may be configured so as to exclude the circuit board 60.

What is claimed is:

1. A power conversion device, comprising:
a first cooler;
a semiconductor module including a main body including a semiconductor element having a first main electrode formed on one surface facing the first cooler and a second main electrode and a pad for signal formed on a rear surface opposite to the one surface, and a plurality of external connection terminals electrically connected to the semiconductor element, the semiconductor module being stacked on the first cooler; and
a second cooler stacked on the semiconductor module on an opposite side to the first cooler so as to face the rear surface, wherein
a length of the second cooler is shorter than a length of the first cooler in one direction perpendicular to a stacking direction of the semiconductor module, the first cooler, and the second cooler,
the plurality of external connection terminals include main terminals having a portion extending in the one direction and electrically connected to a smoothing capacitor, and bent terminals having a first extension portion extending in the one direction on same side of the semiconductor element as the main terminal, and a second extension portion bent with respect to the first extension portion, extending in the stacking direction, and facing the second cooler in the one direction, and a distance between the second extension portion and the second cooler in the one direction is shorter than a distance between the second extension portion and the first cooler.

2. The power conversion device according to claim 1, wherein
the bent terminal is a signal terminal.

3. The power conversion device according to claim 2, wherein
the main body includes a sealing body that seals the semiconductor element, and
the main terminal and the bent terminal protrude from a common side surface of the sealing body to an outside of the sealing body.

4. The power conversion device according to claim 2, wherein
the main body includes a sealing body that seals the semiconductor element, and
the bent terminal protrudes from a surface of the sealing body facing the second cooler to an outside of the sealing body.

5. The power conversion device according to claim 3, wherein
in the one direction, the first cooler is longer than the main body, and
the main terminal faces a base constituting the first cooler in the stacking direction.

6. The power conversion device according to claim 3, further comprising,
an output terminal which is the external connection terminal other than the main terminal, wherein
the main terminal includes a positive terminal electrically connected to a positive electrode of the smoothing capacitor, and a negative terminal electrically connected to a negative electrode of the smoothing capacitor, and
the positive terminal and the negative terminal protrude outside the sealing body from a common side surface of the sealing body, and the output terminal protrudes outside the sealing body from a surface different from the surface from which the positive terminal and the negative terminal protrude.

7. The power conversion device according to claim 3, further comprising,
an insulating member disposed between the second extension portion and the second cooler.

8. The power conversion device according to claim 1, further comprising,
a heat generating component that is in direct contact with a base constituting the first cooler or indirectly via a thermally conductive member.

9. The power conversion device according to claim 8, wherein
the heat generating component is a capacitor component that is arranged alongside the semiconductor module in the one direction and provides the smoothing capacitor.

10. The power conversion device according to claim 8, wherein
the heat generating component has projections and recesses on a contact surface with the base.

11. The power conversion device according to claim 1, wherein
the semiconductor element is arranged closer to the first cooler than the second cooler in the stacking direction.
